(19) United States
(12) Patent Application Publication
(10) Pub. No.: US 2026/0103797 A1
(43) Pub. Date: Apr. 16, 2026

(54) IMPROVING CHEMISTRY UTILIZATION BY INCREASING PRESSURE DURING SUBSTRATE PROCESSING

(71) Applicant: LAM RESEARCH CORPORATION, Fremont, CA (US)

(72) Inventors: Nathaniel Elba RICHEY, Tualatin, OR (US); Gopinath BHIMARASETTI, Portland, OR (US)

(21) Appl. No.: 19/115,826

(22) PCT Filed: Oct. 3, 2023
(86) PCT No.: PCT/US2023/034381

§ 371 Date: Mar. 27, 2025

Related U.S. Application Data
(60) Provisional application No. 63/413,777, filed on Oct. 6, 2022.

(51) Int. Cl. C23C 16/44; C23C 16/455; C23C 16/458; C23C 16/52; H01J 37/32; H10P 14/00

(52) U.S. Cl. CPC C23C 16/4408; C23C 16/45536; C23C 16/45544; C23C 16/45565; C23C 16/4583; C23C 16/52; H01J 37/32357; H01J 37/32816; H01J 2237/1825; H01J 2237/332; H10P 14/00

(57) ABSTRACT

A substrate processing system comprises a processing chamber comprising a pedestal configured to support a substrate. The processing chamber comprises a showerhead configured to supply precursors during dose steps and a purge gas during purge steps of an atomic layer deposition (ALD) process to process the substrate. The dose steps and the purge steps comprise a sequence of a dose step followed by a subsequent purge step. The substrate processing system comprises a throttle valve connected to the processing chamber and a vacuum pump connected to the throttle valve. The substrate processing system comprises a controller configured to control the vacuum pump, open the throttle valve during the purge steps, and close the throttle valve during at least a portion of the dose steps to increase pressure in the processing chamber during at least the portion of the dose steps of the ALD process.

### CROSS-REFERENCE TO RELATED APPLICATIONS

This application claims the benefit of U.S. Provisional Application No. 63/413,777, filed on Oct. 6, 2022. The entire disclosure of the application referenced above is incorporated herein by reference.

### FIELD

The present disclosure relates generally to substrate processing systems and more particularly to a system and method for improving chemistry utilization by increasing pressure during substrate processing.

### BACKGROUND

The background description provided here is for the purpose of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

Atomic Layer Deposition (ALD) is a thin-film deposition method that sequentially performs a gaseous chemical process to deposit a thin film on a surface of a material (e.g., a surface of a substrate such as a semiconductor wafer). Most ALD processes use at least two chemicals called precursors (reactants) that react with the surface of the material one precursor at a time in a sequential, self-limiting manner. For example, a typical ALD process comprises a series of dose and purge steps that are performed sequentially and repeatedly. Through repeated exposure to separate precursors, a thin film is gradually deposited on the surface of the material.

A thermal ALD (T-ALD) process is typically performed in a heated processing chamber. The processing chamber is maintained at a sub-atmospheric pressure using a vacuum pump and a controlled flow of an inert gas (called a trickle). The substrate to be coated with a film is placed in the processing chamber and is allowed to equilibrate with the temperature of the processing chamber before starting the ALD process. A plasma enhanced ALD (PEALD) process uses plasma during dose steps. The plasma may be generated in-situ in the processing chamber. Alternatively, plasma may be generated remotely from the processing chamber and then supplied to the processing chamber.

### SUMMARY

A substrate processing system comprises a processing chamber comprising a pedestal configured to support a substrate. The processing chamber comprises a showerhead configured to supply precursors during dose steps and a purge gas during purge steps of an atomic layer deposition (ALD) process to process the substrate. The dose steps and the purge steps comprise a sequence of a dose step followed by a subsequent purge step. The substrate processing system comprises a throttle valve connected to the processing chamber and a vacuum pump connected to the throttle valve. The substrate processing system comprises a controller configured to control the vacuum pump, open the throttle valve during the purge steps, and close the throttle valve during at least a portion of the dose steps to increase pressure in the processing chamber during at least the portion of the dose steps of the ALD process.

In additional feature, in the sequence, the controller closes the throttle valve after a start of the dose step and before a start of the subsequent purge step, opens the throttle valve at an end of the dose step, keeps the throttle valve open through the subsequent purge step until after a start of a subsequent dose step, and closes the throttle valve after the start of the subsequent dose step.

In additional feature, in the sequence, the controller closes the throttle valve throughout the dose step and opens the throttle valve throughout the subsequent purge step.

In additional feature, in the sequence, the controller closes the throttle valve from a start to an end of the dose step and opens the throttle valve from a start to an end of the subsequent purge step.

In additional feature, in the sequence, the controller closes the throttle valve at an end of the dose step for a predetermined time period, opens the throttle valve at the end of the predetermined time period before a start of the subsequent purge step, keeps the throttle valve open through the subsequent purge step until an end of a subsequent dose step, and closes the throttle valve at the end of the subsequent dose step.

In additional feature, in the sequence, the controller closes the throttle valve before an end of the dose step for a predetermined time period, opens the throttle valve at the end of the predetermined time period before a start of the subsequent purge step, keeps the throttle valve open through the subsequent purge step until before an end of a subsequent dose step, and closes the throttle valve before the end of the subsequent dose step.

In additional feature, the controller is configured to control a speed at which the throttle valve is opened and closed.

In additional feature, the controller is configured to open and close the throttle valve at least partially at different speeds.

In additional feature, the controller is configured to open and close the throttle valve at least partially in a pulsed manner.

In additional feature, the controller is configured to is open and close the throttle valve at least partially at different speeds and at least partially in a pulsed manner.

In additional feature, the substrate processing system further comprises a gas delivery system configured to supply an inert gas to the processing chamber during the ALD process.

In additional feature, the substrate processing system further comprises a gas delivery system configured to supply the precursors to the showerhead during the dose steps and supply the purge gas during the purge steps.

In additional feature, the substrate processing system further comprises a plasma generator arranged external to the processing chamber. The plasma generator is configured to generate plasma and to supply the plasma to the processing chamber through the showerhead during the ALD process.

In additional feature, the controller is configured to turn on the vacuum pump during the ALD process.

In still other features, a method of processing a substrate arranged on a pedestal arranged in a substrate processing system comprises supplying, to a showerhead arranged in the substrate processing system, precursors during dose steps and a purge gas during purge steps of an atomic layer deposition (ALD) process to process the substrate. The dose steps and the purge steps comprise a sequence of a dose step followed by a subsequent purge step. The method comprises opening a throttle valve, connected to the processing chamber and to a vacuum pump, during the purge steps; and closing the throttle valve during at least a portion of the dose steps to increase pressure in the processing chamber during at least the portion of the dose steps of the ALD process.

In additional features, in the sequence, closing the throttle valve during at least the portion of the dose steps comprises closing the throttle valve after a start of the dose step and before a start of the subsequent purge step. The method further comprises opening the throttle valve at an end of the dose step, keeping the throttle valve open through the subsequent purge step until after a start of a subsequent dose step, and closing the throttle valve after the start of the subsequent dose step.

In additional feature, in the sequence, closing the throttle valve during at least the portion of the dose steps comprises closing the throttle valve throughout the dose step, the method further comprising opening the throttle valve throughout the subsequent purge step.

In additional feature, in the sequence, closing the throttle valve during at least the portion of the dose steps comprises closing the throttle valve from a start to an end of the dose step, the method further comprising opening the throttle valve from a start to an end of the subsequent purge step.

In additional features, in the sequence, closing the throttle valve during at least the portion of the dose steps comprises closing the throttle valve at an end of the dose step for a predetermined time period. The method further comprises opening the throttle valve at the end of the predetermined time period before a start of the subsequent purge step, keeping the throttle valve open through the subsequent purge step until an end of a subsequent dose step, and closing the throttle valve at the end of the subsequent dose step.

In additional features, in the sequence, closing the throttle valve during at least the portion of the dose steps comprises closing the throttle valve before an end of the dose step for a predetermined time period. The method further comprises opening the throttle valve at the end of the predetermined time period before a start of the subsequent purge step, keeping the throttle valve open through the subsequent purge step until before an end of a subsequent dose step, and closing the throttle valve before the end of the subsequent dose step.

In additional feature, the method further comprises controlling a speed at which the throttle valve is opened and closed.

In additional feature, the method further comprises opening and closing the throttle valve at least partially at different speeds.

In additional feature, the method further comprises opening and closing the throttle valve at least partially in a pulsed manner.

24. The method of claim 15 further comprising opening and closing the throttle valve at least partially at different speeds and at least partially in a pulsed manner.

In additional feature, the method further comprises supplying an inert gas to the processing chamber during the ALD process.

In additional feature, the method further comprises generating plasma remotely from the processing chamber and supplying the plasma to the processing chamber through the showerhead during the ALD process.

In additional feature, the method further comprises turning on the vacuum pump during the ALD process.

Further areas of applicability of the present disclosure will become apparent from the detailed description, the claims, and the drawings. The detailed description and specific examples are intended for purposes of illustration only and are not intended to limit the scope of the disclosure.

### BRIEF DESCRIPTION OF THE DRAWINGS

The present disclosure will become more fully understood from the detailed description and the accompanying drawings, wherein:

FIG. 1 shows an example of a substrate processing system that processes substrates using a high-pressure step during atomic layer deposition (ALD) according to the present disclosure;

FIGS. 2 and 3A-3D show an example of an ALD process comprising the high-pressure step used to process the substrates in the substrate processing system of FIG. 1 according to the present disclosure; and

FIG. 4 shows an example of a method of processing the substrates in the substrate processing system of FIG. 1 using the ALD process comprising the high-pressure step shown in FIGS. 2 and 3A-3D according to the present disclosure.

In the drawings, reference numbers may be reused to identify similar and/or identical elements.

### DETAILED DESCRIPTION

Chemistry consumption of precursors in tools employing atomic layer deposition (ALD) processes is often not well optimized and results in high chemistry costs. The reason for high chemistry costs is slow chemisorption of the precursors to substrate surfaces. Due to the slow chemisorption, high precursor dose times are typically used. However, a significant amount of the precursor used does not chemisorb and is wasted (purged away), which increases chemistry costs.

Higher utilization of precursor chemistry is needed to reduce chemistry cost. A shorter dose time of precursor can be used to reduce the cost. However, shorter dose times can adversely affect deposition rates and tool throughput. To compensate for the lower dose time of precursor (i.e., to prevent the adverse effects of using lower dose times), the present disclosure adds a higher-pressure step to the recipe, which results in a more efficient consumption of the precursor.

Specifically, following a dose step and before a subsequent purge step (i.e., between a dose step and a subsequent purge step), a high-pressure step is added. The high-pressure step comprises closing a throttle valve connected between the processing chamber and a vacuum pump to maintain pressure in the processing chamber. The high-pressure step increases the absorption of the precursor on the substrate. Using the higher-pressure step, the deposition rate and tool throughput can be maintained while keeping chemistry usage low.

More specifically, in the method of the present disclosure, the precursor dose time is lowered, and the high-pressure step is added after the precursor dose but before the precursor purge step. The high-pressure step comprises closing the throttle valve so that the precursor remains longer in the processing chamber, allowing for more efficient consumption of the chemistry. The high-pressure step significantly reduces chemistry usage while maintaining high deposition rate and throughput.

Thus, adding the high-pressure step to ALD recipes can provide higher chemistry utilization during deposition, which results in lower chemistry usage and chemical costs for deposition processes. The post-dose high-pressure step according to the present disclosure can be added to any ALD process for effectively utilizing chemistry and reducing chemistry waste. These and other features of the present disclosure are described below in further detail.

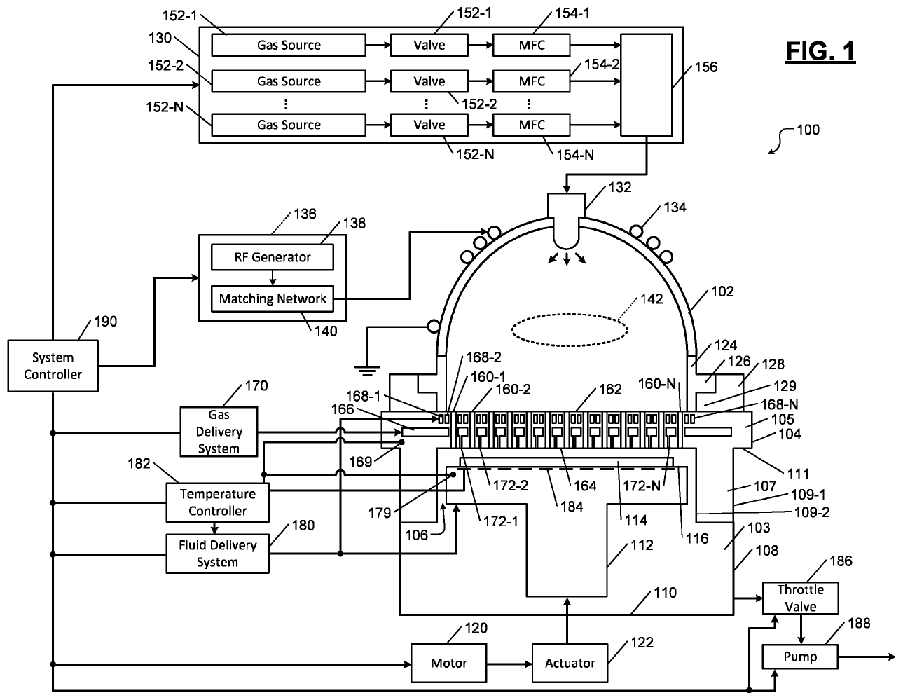

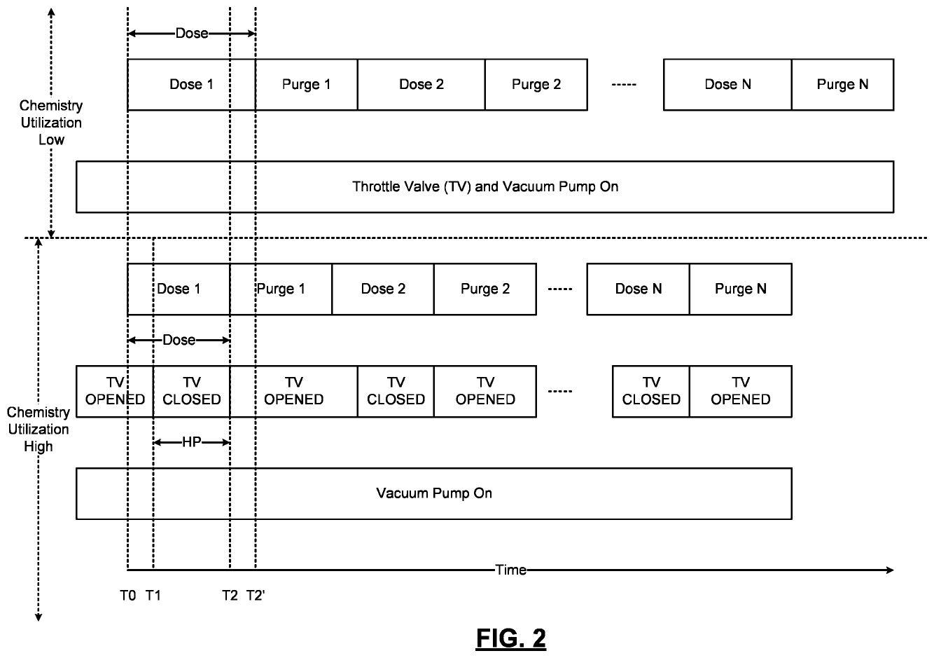

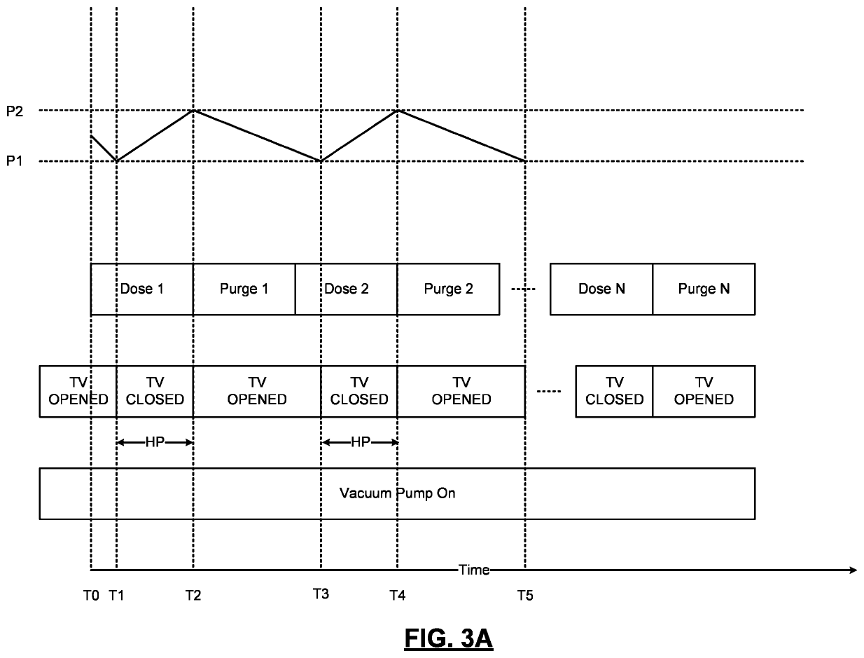

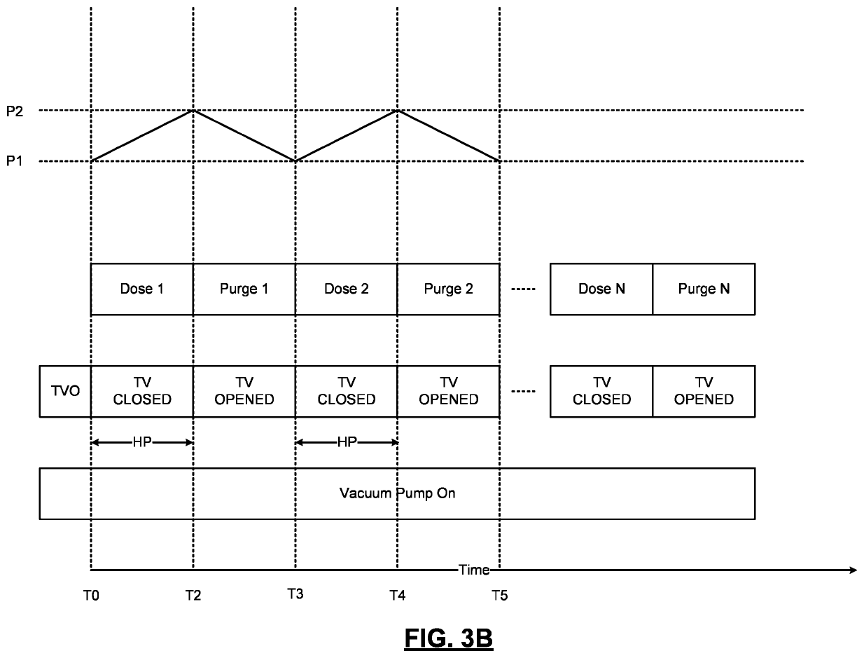

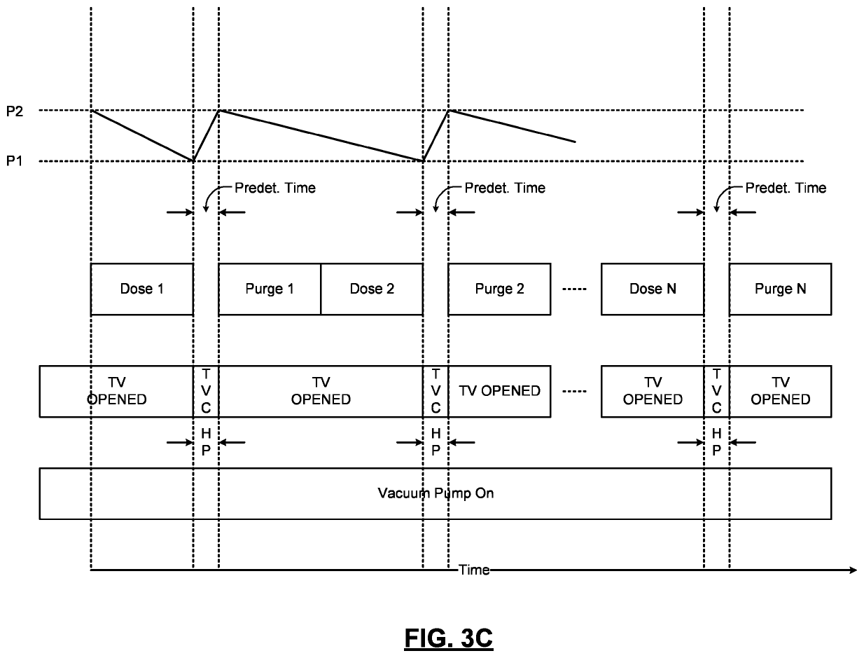

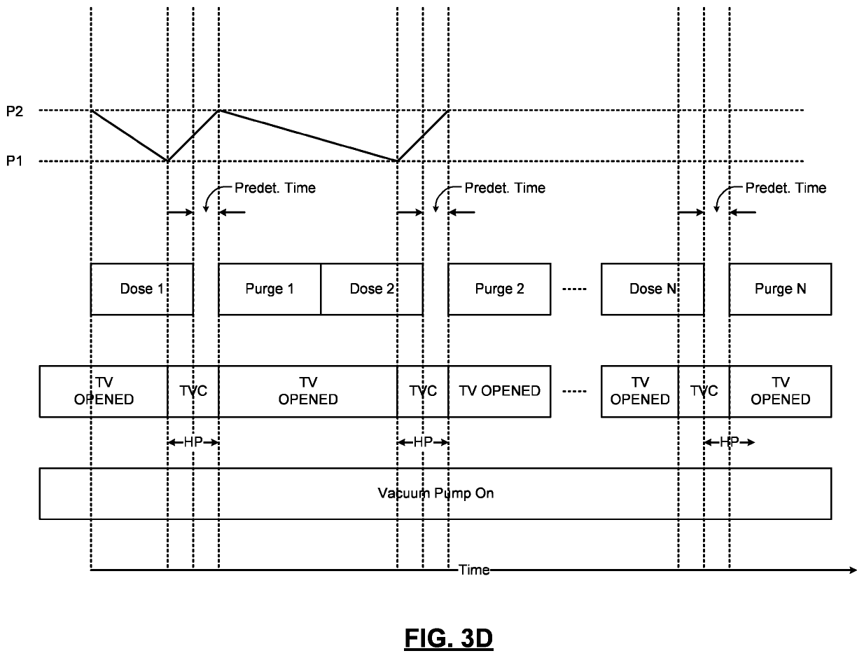

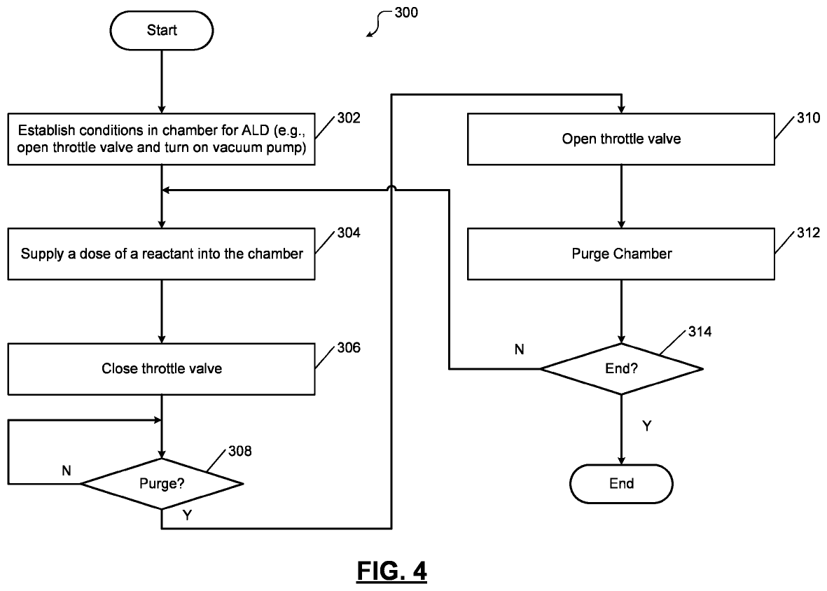

The present disclosure is organized as follows. An example of a substrate processing system that processes substrates using an ALD process comprising the high-pressure step according to the present disclosure is shown and described with reference to FIG. 1. An example of an ALD process comprising the high-pressure step according to the present disclosure is shown and described with reference to FIGS. 2 and 3A-3D. An example of a method for processing a substrate using an ALD process comprising the high-pressure step according to the present disclosure is shown and described with reference to FIG. 4.

### Example of Substrate Processing System

FIG. 1 shows an example of a substrate processing system 100 according to the present disclosure. The substrate processing system 100 comprises a plasma source 102 and a processing chamber 103. The plasma source 102 may be dome-shaped as shown or may be of any other shape. The processing chamber 103 comprises a pedestal 112 and a showerhead 104. The pedestal 112 is arranged in the processing chamber 103. The showerhead 104 is arranged above the pedestal 112 at the top of the processing chamber 103.

The plasma source 102 is arranged above the showerhead 104 to generate a remote plasma 142 as describe below in detail. The showerhead 104 is arranged between the plasma source 102 and the processing chamber 103. The showerhead 104 separates the plasma source 102 from the processing chamber 103. Accordingly, the plasma source 102 is arranged external to and remote from the processing chamber 103. Therefore, the plasma generated in the plasma source 102 is called the remote plasma 142.

The showerhead 104 is described below in detail. Briefly, the showerhead 104 is made of a metal (e.g., aluminum) or an alloy. The showerhead 104 comprises a planar base portion 105 and a cylindrical portion 107 that extends perpendicularly downward from the base portion 105. The base portion 105 extends radially outward at the top of the cylindrical portion 107 forming a flange 111. The cylindrical portion 107 comprises an outer wall 109-1 and an inner wall 109-2. The inner wall 109-2 of the cylindrical portion 107 defines a bore 106 of the showerhead 104. A diameter of the bore 106 is equal to a diameter of the inner wall 109-2 of the cylindrical portion 107 (i.e., an ID of the cylindrical portion 107) of the showerhead 104.

The processing chamber 103 comprises a sidewall 108 and a bottom wall 110. The sidewall 108 is attached to the bottom of the cylindrical portion 107 of the showerhead 104. The sidewall 108 is perpendicular to the base portion 105 of the showerhead 104 and extends vertically downward from the bottom of the outer wall 109-1 of the cylindrical portion 107 of the showerhead 104. The bottom wall 110 of the processing chamber 103 is attached to the sidewall 108 of the processing chamber 103. The bottom wall 110 is parallel to the base portion 105 of the showerhead 104 and perpendicular to the sidewall 108 of the processing chamber 103.

The pedestal 112 is arranged in the processing chamber 103 directly below the showerhead 104. A substrate 114 is arranged on a top surface 116 of the pedestal 112 during processing. The top surface 116 of the pedestal 112 is planar and parallel to the base portion 105 of the showerhead 104 and parallel to the bottom wall 110 of the processing chamber 103. Accordingly, the substrate 114 is parallel to the top surface 116 of the pedestal 112, the base portion 105 of the showerhead 104, and the bottom wall 110 of the processing chamber 103. The ID of the cylindrical portion 107 of the showerhead 104 (i.e., the diameter of the inner wall 109-2 of the showerhead 104) is greater than an OD of the top surface 116 of the pedestal 112. The ID of the cylindrical portion 107 of the showerhead 104 (i.e., the diameter of the inner wall 109-2 of the showerhead 104) is also greater than an OD of the substrate 114.

An actuator 120 driven by a motor 122 can move the pedestal 112 vertically up and down relative to the showerhead 104 within the cylindrical portion 107 of the showerhead 104. A gap between a bottom of the base portion 105 of the showerhead 104 and the top surface 116 of the pedestal 112 may be adjusted by vertically moving the pedestal 112 within the cylindrical portion 107 of the showerhead 104. For example, the gap between the bottom of the base portion 105 of the showerhead 104 and the top surface 116 of the pedestal 112 may be of about 0.2 in., 0.15 in., or 0.11 in.

A bottom end of the plasma source 102 is open and is attached to a top end of a first cylindrical component 124. The first cylindrical component 124 is arranged at a periphery of the planar base portion 105 of the showerhead 104. The first cylindrical component 124 comprises a first flange 126. The first flange 126 extends radially outwardly from about a center of the first cylindrical component 124. Accordingly, the first cylindrical component 124 has a shape of the letter “T” with the letter “T” rotated left by 90 degrees.

A second cylindrical component 128 surrounds the first cylindrical component 124. The second cylindrical component 128 comprises a second flange 129 that extends radially inwardly from a bottom end of the second cylindrical component 128. Accordingly, the second cylindrical component 128 has a shape of the letter “L” with the letter “L” flipped horizontally. The first flange 126 of the first cylindrical component 124 overhangs the second flange 129 of the second cylindrical component 128. The bottom ends of the first and second cylindrical components 124, 128 are attached to the top of the base portion 105 of showerhead 104 near the periphery of the base portion 105 of the showerhead 104.

The substrate processing system 100 comprises a gas delivery system 130. The gas delivery system 130 comprises one or more gas sources 150-1, 150-2, . . . , and 150-N (collectively, the gas sources 150), where N is an integer greater than one. The gas sources 150 supply one or more process gases, purge gases (e.g., inert gases), cleaning gases, and so on. The gas sources 150 are connected by respective valves 152-1, 152-2, . . . , and 152-N (collectively, the valves 152) to mass flow controllers 154-1, 154-2, . . . , and 154-N (collectively, the MFCs 154). The MFCs 154 control mass flow of the gases supplied by the gas sources 150. The MFCs 154 supply the gases to a manifold 156.

The plasma source 102 comprises a gas injector 132 arranged at the top of the plasma source 102. The gas injector 132 is connected to the manifold 156. The gas injector 132 receives one or more gases from the gas delivery system 130 via the manifold 156. The gas injector 132 supplies the one or more gases received from the gas delivery system 130 via the manifold 156 into the plasma source 102. The plasma source 102 generates the remote plasma 142 (i.e., plasma generated outside the processing chamber 103) as follows.

A coil 134 is arranged around the plasma source 102. A first end of the coil 134 is grounded, and a second end of the coil 134 is connected to an RF generating system 136. The RF generating system 136 comprises an RF generator 138 that generates the RF power. The RF power is fed by a matching network 140 to the coil 134. The RF power supplied to the coil 134 ignites the gas or gases injected by the gas injector 132 from the gas delivery system 130 into the plasma source 102 and generates the remote plasma 142 in the plasma source 102. Since the plasma source 102 generates the plasma remotely from (i.e., outside) the processing chamber 103, the plasma generated in the plasma source 102 is called the remote plasma 142.

The showerhead 104 is now described in further detail. The showerhead 104 supplies the gases received from the gas delivery system 130, the remote plasma 142 generated in the plasma source 102, or both from the plasma source 102 into the processing chamber 103. The base portion 105 of the showerhead 104 comprises a first set of through holes (also called radical holes) 160-1, 160-2, . . . , and 160-N (collectively, the radical holes 160), where N is an integer greater than one. The radical holes 160 extend from a top surface 162 of the base portion 105 of the showerhead 104 to a substrate-facing bottom surface 164 of the base portion 105 of the showerhead 104 (also called a faceplate 164). Radicals from the remote plasma 142 in the plasma source 102 pass through the radical holes 160 into the processing chamber 103.

Additionally, the base portion 105 of the showerhead 104 comprises a plenum 166 that is separate from and that is not in fluid communication with the radical holes 160. The plenum 166 receives one or more precursor gases during dose steps of an ALD process from a second gas delivery system 170. The plenum 166 may also receive a purge gas (e.g., an inert gas) during purge steps of an ALD process from the second gas delivery system 170. Optionally, the purge gases may be supplied by the gas delivery system 130 through the gas injector 132.

The base portion 105 of the showerhead 104 further comprises a second set of holes (also called precursor holes) 172-1, 172-2, . . . , and 172-N (collectively, the precursor holes 172), where N is an integer greater than one. The precursor holes 172 extend from the plenum 166 to the faceplate 164 of the showerhead 104. One or more precursors supplied by the second gas delivery system 170 flow through the precursor holes 172 into the processing chamber 103. The radical holes 160 are not in fluid communication with the plenum 166 and the precursor holes 172. The radical holes 160 are greater in diameter and length than the precursor holes 172.

The base portion 105 of the showerhead 104 further comprises a plurality of grooves 168-1, 168-2, . . . , and 168-N (collectively, the grooves 168), where N is an integer greater than 1. The grooves 168 form a cooling channel. A fluid delivery system 180 supplies a coolant to the grooves 168 through an inlet (not shown) in the base portion 105 of the showerhead 104.

One or more temperature sensors 169 are disposed in the base portion 105 of the showerhead 104. The temperature sensors 169 are connected to a temperature controller 182. The temperature controller 182 controls the supply of the coolant from the fluid delivery system 180 to the grooves 168 to control the temperature of the showerhead 104.

Further, the pedestal 112 comprises one or more heaters 184, a cooling system (not shown) that receives a coolant from the fluid delivery system 180, and one or more temperature sensors 179. The temperature controller 182 is connected to the temperature sensors 179 in the pedestal 112. The temperature controller 182 controls power supply to the heaters 184. The temperature controller 182 controls the supply of the coolant from the fluid delivery system 180 to the cooling system in the pedestal 112 to control the temperature of the pedestal 112.

A throttle valve 186 and a vacuum pump 188 control pressure in the processing chamber 103 and evacuate reactants from the processing chamber 103 during processing. A system controller 190 controls the components of the substrate processing system 100 described above. Specifically, the system controller 190 controls the throttle valve 186 to add the high-pressure step according to the present disclosure during the processing of the substrate 114 as described below in detail.

### Examples of Added High-Pressure Step

The substrate processing system 100 performs an ALD process on the substrate 114 using the high-pressure step according to the present disclosure as follows. The high-pressure step is described below in detail with reference to FIGS. 2 and 3. An example of a method for processing the substrate 114 comprising the high-pressure step is described below in detail with reference to FIG. 4.

FIGS. 2 and 3A-3D show examples of ALD processes with and without the added high-pressure step. Initially, in an upper half of FIG. 2 (identified as “Chemistry Utilization Low”), an example of an ALD process without the high-pressure step is shown and described to illustrate the problem solved by adding the high-pressure step. Subsequently, in a lower half of FIG. 2 (identified as “Chemistry Utilization High”) and in FIGS. 3A-3D, an example of an ALD process comprising the high-pressure step is shown and described to illustrate the solution provided by the present disclosure. In FIGS. 2 and 3A-3D, the acronyms HP and TV respectively denote the high-pressure step and the throttle valve 186 as described below.

In the upper half of FIG. 2, an ALD process comprises a sequence of dose steps and purge steps used during the processing of the substrate 114. For example, the sequence comprises a first dose step Dose 1, followed by a first purge step Purge 1, followed by a second dose step Dose 2, followed by a second purge step Purge 2, and so on. In the sequence, a first precursor is supplied to the showerhead 104 during the first dose step Dose 1, and a second precursor is supplied to the showerhead 104 during the second dose step Dose 2. A purge gas (e.g., and inert gas) is supplied to the showerhead 104 during the first and second purge steps Purge 1 and Purge 2 to evacuate byproducts produced during the first and second dose steps Dose 1 and Dose 2 from the processing chamber 103. Dose 1 starts at time T0 and ends at time T2′. Purge 1 starts at time T2′. The next dose step Dose 2 starts when the purge step Purge 1 ends. The Dose 2 step is followed by the Purge 2 step, and so on.

The sequence of the steps Dose 1, Purge 1, Dose 2, and Purge 2 is repeated, as indicated by an N^{th} dose step Dose N and an N^{th} purge step Purge N, until the processing of the substrate 114 is completed. During the processing, the throttle valve 186 is open, and the vacuum pump 188 is turned on. The sequence does not use the high-pressure step of the present disclosure.

As explained above, chemistry consumption of the precursors in the ALD process shown in the upper half of FIG. 2 results in high chemistry costs. The reason for high chemistry costs is slow chemisorption of the precursors to substrate surfaces. Due to the slow chemisorption, high precursor dose times are typically used. However, a significant amount of the precursor used does not chemisorb and is wasted (purged away), which increases chemistry costs.

Higher utilization of precursor chemistry is needed to reduce chemistry cost. While a shorter dose time of precursor can be used to reduce the cost, shorter dose times can adversely affect deposition rates and tool throughput. To compensate for the lower dose time of precursor (i.e., to prevent the adverse effects of using lower dose times), the present disclosure adds a higher-pressure step to the process recipe as follows, which results in a more efficient consumption of the precursor (shown in the lower half of FIG. 2 and in FIGS. 3A-3D).

In the lower half of FIG. 2 and in FIGS. 3A-3D, an ALD process comprising the added higher-pressure step according to the present disclosure is shown. In FIG. 2 and in FIGS. 3A-3D, the ALD process comprises essentially the same sequence of dose and purge steps as those described above with reference to the upper half of FIG. 2 with two exceptions. First, the dose time (i.e., the duration of each dose step) is reduced from (T0 to T2′) shown in the upper half of FIG. 2 to (T0−T2) shown in the lower half of FIG. 2, where T2 is less than T2′. That is, the duration (T0−T2) of each dose step in the lower half of FIG. 2 is less than the duration (T0 to T2′) of each dose step in the upper half of FIG. 2. Second, the high-pressure step (described below) is added following the start of each dose step and before the start of the subsequent purge step (i.e., between each dose step and subsequent purge step) as follows.

For example, a first implementation of the high-pressure (HP) step is shown in the lower half of FIG. 2 and in FIG. 3A. Other implementations of the high-pressure step are shown and described below with reference to FIGS. 3B-3D. In the first implementation shown in FIG. 3A, the high-pressure step is started at time T1 following the start of the dose step at time T0 and before the end of the dose step at time T2 (i.e., before the beginning of the subsequent purge step at time T2). The high-pressure step ends at time T2 (i.e., at the end of the dose step Dose 1 and at the beginning of the subsequent purge step Purge 1). The duration of the high-pressure step is equal to (T2−T1). That is, the high-pressure step is added during a portion of the dose step Dose 1 and before the beginning of the subsequent purge step Purge 1 at time T2. Thus, the high-pressure step is added between the dose step Dose 1 and the subsequent purge step Purge 1. The high-pressure step is added in the remainder of the sequence of the dose and purge steps using the same procedure.

Alternatively, in a second implementation shown in FIG. 3B, the high-pressure step can be started at the start of the dose step Dose 1 at time T0 and can be ended at the end of the dose step Dose 1 at time T2, at which time the subsequent purge step Purge 1 is started. In the second implementation, the duration of the high-pressure step is equal to (T2−T0). That is, the high-pressure step is added during the entire dose step Dose 1 and before the beginning of the subsequent purge step Purge 1 at time T2. The high-pressure step is added in the remainder of the sequence of the dose and purge steps in the ALD process using the same procedure.

In a third implementation shown in FIG. 3C, the high-pressure step can be started at the end of the dose step Dose 1 at time T2. The subsequent purge step Purge 1 can be delayed for a predetermined time period following the end of the dose step Dose 1 at time T2. The high-pressure step can be ended and the subsequent purge step Purge 1 can be started at time (T2+the predetermined time period). In the third implementation, the duration of the high-pressure step is equal to the predetermined time period. That is, the high-pressure step is added after the end of the dose step and before the beginning of the subsequent purge step. Thus, in the third implementation, the high-pressure step is added between the dose step and the subsequent purge step. The high-pressure step is added in the remainder of the sequence of the dose and purge steps in the ALD process using the same procedure.

In a variation of the third implementation shown in FIG. 3D, the high-pressure step can be started slightly before the end of the dose step Dose 1 at time T2. The remainder of the variation can be similar to rest of the third implementation described above except that due to the slightly earlier start of the high-pressure step, the duration of the high-pressure step will be slightly greater than the predetermined time period.

In general, the high-pressure step is added between the dose step and the subsequent purge step. Depending on the implementation, the high-pressure step may overlap the dose step. For example, the high-pressure step partially overlaps the dose step in the first implementation (shown in FIG. 3A) and in the variation of the third implementation (shown in FIG. 3D), and the high-pressure step fully overlaps the dose step in the second implementation (shown in FIG. 3B). Regardless of the implementation used, the high-pressure step precedes the purge step that follows the dose step in the sequence of the dose and purge steps of the ALD process. Throughout the present disclosure, the subsequent purge step is a purge step that follows a preceding dose step. Stated differently, an i^{th} purge step follows an i^{th} dose step.

The high-pressure step is added to maintain high pressure in the processing chamber 103 during or after the dose step (depending on which implementation of the high-pressure step is used) and before the subsequent purge step. The high-pressure step allows the precursor supplied in the dose step to remain in the processing chamber 103, which allows shorter dose times and reduced chemistry cost without sacrificing deposition rates and tool throughput.

The procedure of adding the high-pressure step is repeated for each dose step and subsequent purge step in the sequence of the dose and purge steps in the ALD process. Accordingly, while the times T0, T1, and T2 are shown to illustrate the high-pressure step for only one dose step in FIG. 2, respectively similar times (e.g., times T4, T5, and T6 shown in FIG. 3A) are used to add the high-pressure step for each subsequent dose and purge steps in the sequence that is repeated until the processing of the substrate 114 is completed.

The high pressure in the processing chamber 103 provided by the added high-pressure step results in higher utilization of precursor chemistry, which reduces chemistry cost. Specifically, due to the high pressure in the processing chamber 103 provided by the added high-pressure step, a shorter dose time of precursor ((T2−T0) as compared to (T2′−T0) without the high-pressure step as shown in the upper half of FIG. 2) can be used to reduce the cost. The shorter dose times do not adversely affect deposition rates and tool throughput since the shorter does times are compensated by the high-pressure step, which increases the chemisorption rate of the precursor despite the shorter dose times. Thus, the high-pressure step results in shorter dose times, higher utilization of precursor chemistry, and reduced chemistry cost without sacrificing deposition rates and tool throughput.

The high-pressure in the processing chamber 103 is achieved as follows. For example, in the first implementation of the high-pressure step shown in the lower half of FIG. 2 and in FIG. 3A, the high-pressure step is started at time T1 and ended at time T2. The high pressure in the processing chamber 103 is achieved by closing the throttle valve 186 from time T1 to time T2. Specifically, the throttle valve 186 is opened from time T0 to time T1, closed from T1 to time T2, and opened at time T2. The throttle valve 186 is kept open from time T2 through the subsequent purge step until the start of the next high-pressure step (e.g., until time T3 shown in FIG. 3A). The high-pressure step is started (i.e., the throttle valve 186 is closed) at time T3 after the start of the next dose step. The procedure of opening and closing the throttle valve 186 described above is repeated through the subsequent dose and purge steps until the processing of the substrate 114 is completed.

During the high-pressure step, with the throttle valve 186 closed, the pressure in the processing chamber rises due to many factors. For example, since the throttle valve 186 is closed, the processing chamber 103 is not evacuated during the high-pressure step. Additionally, during the high-pressure step, controlled flow of some gases such as an inert gas (called the trickle) continues through the processing chamber 103 (e.g., through the showerhead 104). The controlled flow of these gases increases the pressure in the processing chamber 103 since the processing chamber 103 is not evacuated during the high-pressure step due to the throttle valve 186 being closed. Additionally, process byproducts generated during the dose step, which are not evacuated from the processing chamber 103 since the throttle valve 186 closed, also cause increase the pressure in the processing chamber 103. Thus, the pressure in the processing chamber 103 increases from P1 to P2 during the high-pressure step (e.g., from time T1 to T2 shown in FIG. 3A). Since the throttle valve 186 is closed, the high-pressure step causes the precursor to remain in the processing chamber 103 longer (soaking), allowing for more efficient consumption of the chemistry.

At the end of the high-pressure step, the throttle valve 186 is opened from time T2 to T3 (shown in FIG. 3A), and the vacuum pump 186 evacuates the processing chamber 103 during the subsequent purge step (e.g., from time T2 to T3 shown in FIG. 3A). Accordingly, the pressure in the processing chamber 103 decreases from P2 to P1 during the subsequent purge step (e.g., from time T2 to T3 shown in FIG. 3A).

While the increase and decease in the pressure in the processing chamber 103 is shown linearly in FIG. 3A, the throttle valve 186 can be opened and closed gradually in other ways (e.g., non-linearly). The increase and decease in the pressure in the processing chamber 103 can be gradual based on a speed at which the throttle valve 186 is closed and opened. The speed at which the throttle valve 186 is closed and opened can be controlled (e.g., by the system controller 190 shown in FIG. 1) to control the rate at which the pressure in the pressure in the processing chamber 103 is increased and deceased. The rate at which the pressure in the pressure in the processing chamber 103 increases and decreases is proportional to the speed at which the throttle valve 186 is closed and opened.

In some examples, instead of the gradual operation, the throttle valve 186 can be opened and closed in a stepped or pulsed manner by the system controller 190 shown in FIG. 1. In other examples, the throttle valve 186 can be opened and closed at different speeds. In further examples, the throttle valve 186 can be opened and closed using a combination of the gradual operation and the stepped or pulsed operation. Further, the throttle valve 186 can be opened at different speeds. For example, the throttle valve 186 can be partially opened at a first speed, and the remainder of the throttle valve 186 can be opened at a second speed. Similarly, the throttle valve 186 can be partially closed at a first speed, and the remainder of the throttle valve 186 can be closed at a second speed. Furthermore, the stepped or pulsed operation can be used during the partial opening and the partial closing of the throttle valve 186 and/or the opening and the closing of the remainder of the throttle valve 186.

Alternatively, the throttle valve 186 can be closed and opened to implement the high-pressure step at different times depending on the implementation of the high-pressure step. For example, in the second implementation of the high-pressure step described above and shown in FIG. 3B, the high pressure in the processing chamber 103 can be achieved by closing the throttle valve 186 from time T0 to time T2 (i.e., throughout the entire dose step). The throttle valve 186 is opened from time T2 to time T3 (i.e., throughout the entire purge step following the dose step). The procedure of opening and closing the throttle valve 186 is repeated through the subsequent dose and purge steps until the processing of the substrate 114 is completed.

In the third implementation of the high-pressure step described above and shown in FIG. 3C, the high pressure in the processing chamber 103 can be achieved by closing the throttle valve 186 at time T2 (i.e., at the end of the dose step). The throttle valve 186 is closed from time T2 for the predetermined time period until the start of subsequent purge step. The throttle valve 186 is opened at the start of the subsequent purge step. The procedure of opening and closing the throttle valve 186 is repeated through the subsequent dose and purge steps until the processing of the substrate 114 is completed.

In the variation of the third implementation of the high-pressure step described above and shown in FIG. 3D, the high pressure in the processing chamber 103 can be achieved by closing the throttle valve 186 slightly before the end of the dose step Dose 1 at time T2. The throttle valve 186 is open until slightly before the end of the dose step at time T2. The throttle valve 186 remains closed from slightly before time T2 and through the predetermined time period following time T2 until the start of subsequent purge step. The throttle valve 186 is opened at the start of the subsequent purge step. The procedure of opening and closing the throttle valve 186 is repeated through the subsequent dose and purge steps until the processing of the substrate 114 is completed.

In the lower half of FIG. 2 and in FIGS. 3A-3D, along with the dose steps Dose 1 to Dose N, the purge steps Purge 1 to Purge N, and the high-pressure steps HP, the durations for which the throttle valve 186 is opened and closed are indicated by indications TV OPENED (or TVO) and TV CLOSED (or TVC). The vacuum pump 188 is on throughout the ALD process comprising the dose, purge, and high-pressure steps. The pressure P1 is near vacuum, and the pressure P2 is slightly above vacuum. In the high-pressure step, the pressure P2 can also be achieved by partially closing the throttle valve 186. Therefore, throughout the present disclosure, the description of closing the throttle valve 186 also includes partially closing the throttle valve 186.

In all implementations of the high-pressure step described above, the increase in pressure in the processing chamber 103 is achieved due to the factors described above with reference to the first implementation of the high-pressure step. Since the throttle valve 186 is closed, the high-pressure step causes the precursor to remain in the processing chamber 103 longer (soaking), allowing for more efficient consumption of the chemistry. Further, in these implementations, the throttle valve 186 can be controlled in the manner described above with reference to the first implementation of the high-pressure step. Accordingly, in these implementations, the rate at which the pressure in the processing chamber 103 increases and decreases is proportional to the speed at which the throttle valve 186 is closed and opened.

### Method of Added High-Pressure Step

FIG. 4 shows an example of a method 300 for processing the substrate 114 in the substrate processing system of FIG. 1 using the ALD process comprising the high-pressure step shown in FIGS. 2 and 3 according to the present disclosure. For example, the system controller 190 of the substrate processing system 100 performs the method 300 as follows.

At 302, conditions for performing the ALD process on the substrate 114 are established in the processing chamber 103. For example, if a thermal ALD process is to be performed on the substrate 114, the pedestal 112 and the showerhead 104 are heated. If a PEALD process is to be performed on the substrate 114, the remote plasma 142 is generated in the plasma source 102. The throttle valve 186 is opened, and the vacuum pump 188 is turned on to evacuate the processing chamber. The substrate 114 is loaded into the processing chamber 103.

At 304, the system controller 190 controls the second gas delivery system 170 to supply a dose of a precursor into the processing chamber 103. At 306, depending on the implementation used to add the high-pressure step, the system controller 190 closes the throttle valve 186 at an appropriate time between the dose step and the subsequent purge step as described above with reference to FIGS. 2 and 3.

At 308, the system controller 190 determines if the time to perform the purge step is reached. At 310, if the time to perform the purge step is reached, the system controller 190 opens the throttle valve 186 as described above with reference to FIGS. 2 and 3. At 312, the vacuum pump 188 purges the processing chamber 103.

At 314, the system controller 190 determines if the processing of the substrate 114 is complete. The method 300 ends if the processing of the substrate 114 is complete. The method 300 repeats the steps 304 to 312 if the processing of the substrate 114 is not yet complete. When repeating the steps 304 to 312, the method selects appropriate precursors as described above with reference to FIGS. 2 and 3. Additionally, throughout the method 300, the system controller 190 also controls the flow of other gases (e.g., an inert gas or the trickle) To maintain the high pressure during the high-pressure step.

The foregoing description is merely illustrative in nature and is not intended to limit the disclosure, its application, or uses. The broad teachings of the disclosure can be implemented in a variety of forms. Therefore, while this disclosure includes particular examples, the true scope of the disclosure should not be so limited since other modifications will become apparent upon a study of the drawings, the specification, and the following claims.

It should be understood that one or more steps within a method may be executed in different order (or concurrently) without altering the principles of the present disclosure. Further, although each of the embodiments is described above as having certain features, any one or more of those features described with respect to any embodiment of the disclosure can be implemented in and/or combined with features of any of the other embodiments, even if that combination is not explicitly described. In other words, the described embodiments are not mutually exclusive, and permutations of one or more embodiments with one another remain within the scope of this disclosure.

Spatial and functional relationships between elements (for example, between modules, circuit elements, semiconductor layers, etc.) are described using various terms, including “connected,” “engaged,” “coupled,” “adjacent,” “next to,” “on top of,” “above,” “below,” and “disposed.” Unless explicitly described as being “direct,” when a relationship between first and second elements is described in the above disclosure, that relationship can be a direct relationship where no other intervening elements are present between the first and second elements but can also be an indirect relationship where one or more intervening elements are present (either spatially or functionally) between the first and second elements. As used herein, the phrase at least one of A, B, and C should be construed to mean a logical (A OR B OR C), using a non-exclusive logical OR, and should not be construed to mean “at least one of A, at least one of B, and at least one of C.”

In some implementations, a controller is part of a system, which may be part of the above-described examples. Such systems can comprise semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The electronics may be referred to as the “controller,” which may control various components or subparts of the system or systems.

The controller, depending on the processing requirements and/or the type of system, may be programmed to control any of the processes disclosed herein, including the delivery of processing gases, temperature settings (e.g., heating and/or cooling), pressure settings, vacuum settings, power settings, radio frequency (RF) generator settings, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the controller may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software).

Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The controller, in some implementations, may be a part of or coupled to a computer that is integrated with the system, coupled to the system, otherwise networked to the system, or a combination thereof. For example, the controller may be in the “cloud” or all or a part of a fab's host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process.

In some examples, a remote computer (e.g., a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. It should be understood that the parameters may be specific to the type of process to be performed and the type of tool that the controller is configured to interface with or control.

Thus, as described above, the controller may be distributed, such as by comprising one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

What is claimed is:

1. A substrate processing system comprising:
a processing chamber comprising a pedestal configured to support a substrate and a showerhead configured to supply precursors during dose steps and a purge gas during purge steps of an atomic layer deposition (ALD) process to process the substrate, wherein the dose steps and the purge steps comprise a sequence of a dose step followed by a subsequent purge step;
a throttle valve connected to the processing chamber;
a vacuum pump connected to the throttle valve; and
a controller configured to control the vacuum pump, open the throttle valve during the purge steps, and close the throttle valve during at least a portion of the dose steps to increase pressure in the processing chamber during at least the portion of the dose steps of the ALD process.

2. The substrate processing system of claim 1 wherein in the sequence, the controller closes the throttle valve after a start of the dose step and before a start of the subsequent purge step, opens the throttle valve at an end of the dose step, keeps the throttle valve open through the subsequent purge step until after a start of a subsequent dose step, and closes the throttle valve after the start of the subsequent dose step.

3. The substrate processing system of claim 1 wherein in the sequence, the controller closes the throttle valve throughout the dose step and opens the throttle valve throughout the subsequent purge step.

4. The substrate processing system of claim 1 wherein in the sequence, the controller closes the throttle valve from a start to an end of the dose step and opens the throttle valve from a start to an end of the subsequent purge step.

5. The substrate processing system of claim 1 wherein in the sequence, the controller closes the throttle valve at an end of the dose step for a predetermined time period, opens the throttle valve at the end of the predetermined time period before a start of the subsequent purge step, keeps the throttle valve open through the subsequent purge step until an end of a subsequent dose step, and closes the throttle valve at the end of the subsequent dose step.

6. The substrate processing system of claim 1 wherein in the sequence, the controller closes the throttle valve before an end of the dose step for a predetermined time period, opens the throttle valve at the end of the predetermined time period before a start of the subsequent purge step, keeps the throttle valve open through the subsequent purge step until before an end of a subsequent dose step, and closes the throttle valve before the end of the subsequent dose step.

7. The substrate processing system of claim 1 wherein the controller is configured to control a speed at which the throttle valve is opened and closed.

8. The substrate processing system of claim 1 wherein the controller is configured to open and close the throttle valve at least partially at different speeds.

9. The substrate processing system of claim 1 wherein the controller is configured to open and close the throttle valve at least partially in a pulsed manner.

10. The substrate processing system of claim 1 wherein the controller is configured to is open and close the throttle valve at least partially at different speeds and at least partially in a pulsed manner.

11. The substrate processing system of claim 1 further comprising a gas delivery system configured to supply an inert gas to the processing chamber during the ALD process.

12. The substrate processing system of claim 1 further comprising a gas delivery system configured to supply the precursors to the showerhead during the dose steps and supply the purge gas during the purge steps.

13. The substrate processing system claim 1 further comprising a plasma generator arranged external to the processing chamber wherein the plasma generator is configured to generate plasma and to supply the plasma to the processing chamber through the showerhead during the ALD process.

14. The substrate processing system of claim 1 wherein the controller is configured to turn on the vacuum pump during the ALD process.

15. A method of processing a substrate arranged on a pedestal arranged in a substrate processing system, the method comprising:
supplying, to a showerhead arranged in the substrate processing system, precursors during dose steps and a purge gas during purge steps of an atomic layer deposition (ALD) process to process the substrate, wherein the dose steps and the purge steps comprise a sequence of a dose step followed by a subsequent purge step;
opening a throttle valve, connected to the processing chamber and to a vacuum pump, during the purge steps; and
closing the throttle valve during at least a portion of the dose steps to increase pressure in the processing chamber during at least the portion of the dose steps of the ALD process.

16. The method of claim 15 wherein in the sequence, closing the throttle valve during at least the portion of the dose steps comprises closing the throttle valve after a start of the dose step and before a start of the subsequent purge step, the method further comprising:
opening the throttle valve at an end of the dose step;
keeping the throttle valve open through the subsequent purge step until after a start of a subsequent dose step; and
closing the throttle valve after the start of the subsequent dose step.

17. The method of claim 15 wherein in the sequence, closing the throttle valve during at least the portion of the dose steps comprises closing the throttle valve throughout the dose step, the method further comprising opening the throttle valve throughout the subsequent purge step.

18. The method of claim 15 wherein in the sequence, closing the throttle valve during at least the portion of the dose steps comprises closing the throttle valve from a start to an end of the dose step, the method further comprising opening the throttle valve from a start to an end of the subsequent purge step.

19. The method of claim 15 wherein in the sequence, closing the throttle valve during at least the portion of the dose steps comprises closing the throttle valve at an end of the dose step for a predetermined time period, the method further comprising:
opening the throttle valve at the end of the predetermined time period before a start of the subsequent purge step;
keeping the throttle valve open through the subsequent purge step until an end of a subsequent dose step; and
closing the throttle valve at the end of the subsequent dose step.

20. The method of claim 15 wherein in the sequence, closing the throttle valve during at least the portion of the dose steps comprises closing the throttle valve before an end of the dose step for a predetermined time period, the method further comprising:
opening the throttle valve at the end of the predetermined time period before a start of the subsequent purge step;
keeping the throttle valve open through the subsequent purge step until before an end of a subsequent dose step; and
closing the throttle valve before the end of the subsequent dose step.

21. The method of claim 15 further comprising controlling a speed at which the throttle valve is opened and closed.

22. The method of claim 15 further comprising opening and closing the throttle valve at least partially at different speeds.

23. The method of claim 15 further comprising opening and closing the throttle valve at least partially in a pulsed manner.

24. The method of claim 15 further comprising opening and closing the throttle valve at least partially at different speeds and at least partially in a pulsed manner.

25. The method of claim 15 further comprising supplying an inert gas to the processing chamber during the ALD process.

26. The method of claim 15 further comprising generating plasma remotely from the processing chamber and supplying the plasma to the processing chamber through the showerhead during the ALD process.

27. The method of claim 15 further comprising turning on the vacuum pump during the ALD process.
